(19) United States
(12) Patent Application Publication
(10) Pub. No.: US 2026/0229259 A1
(43) Pub. Date: Aug. 6, 2026

(54) METHOD OF DETECTING SENSE MARGIN OF MEMORY READ OPERATION AND RELATED SENSE MARGIN DETECTING CIRCUIT

(71) Applicant: UNITED MICROELECTRONICS CORP., Hsin-Chu City (TW)

(72) Inventors: Chin-Hsun Yeh, Tainan City (TW); Min-Chia Wang, New Taipei City (TW)

(73) Assignee: UNITED MICROELECTRONICS CORP., Hsin-Chu City (TW)

(21) Appl. No.: 19/057,921

(22) Filed: Feb. 19, 2025

(30) Foreign Application Priority Data
Feb. 4, 2025 (TW) 114103941

(51) Int. Cl. G11C 7/08; G11C 7/06

(52) U.S. Cl. CPC G11C 7/08; G11C 7/065

(57) ABSTRACT

During a first phase, a bit line voltage is transmitted to a first input end of a sense amplifier and a reference voltage is transmitted to a second input end of the sense amplifier, so that the sense amplifier outputs data based on a first voltage difference between its first and second input ends for providing a first data signal. During a second phase, the reference voltage is transmitted to the first input end of the sense amplifier and the bit line voltage is transmitted to the second input end of the sense amplifier, so that the sense amplifier outputs data based on a second voltage difference between its first and second input ends for providing a second data signal. During a third phase, a sense margin detecting signal is provided based on the first data signal and the second data signal.

### BACKGROUND OF THE INVENTION

### 1. Field of the Invention

The present invention is related to a sense margin detecting method of memory reading operation and a related sense margin detecting circuit.

### 2. Description of the Prior Art

A sense amplifier is a differential amplifier that amplifies the voltage difference between its two input ends and then outputs the amplified voltage, and is an important circuit in a memory device. The sense margin of memory read operation refers to the sensing ability of the sense amplifier to compare the voltage signal stored in the memory with a reference voltage and then the amplification ability of weak voltage difference, which is an important indicator of its operational performance. If the input data exceeds its sense margin, the sense amplifier may output erroneous data, which may cause the memory read operation to fail.

Therefore, there is a need for a sense margin detecting method of memory reading operation and a related sense margin detecting circuit.

### SUMMARY OF THE INVENTION

The present invention provides a method of detecting a sense margin of memory read operation. A bit line voltage is transmitted to a first input end of a sense amplifier and a reference voltage is transmitted to a second input end of the sense amplifier during a first phase. The sense amplifier outputs a data signal based on a first voltage difference between the first input end and the second input end of the sense amplifier for providing a corresponding first data signal during the first phase. The reference voltage is transmitted to the first input end of the sense amplifier and the bit line voltage is transmitted to the second input end of the sense amplifier during a second phase. The sense amplifier outputs the data signal based on a second voltage difference between the first input end and the second input end of the sense amplifier for providing a corresponding second data signal during the second phase. A sense margin detecting signal is provided based on the first data signal and the second data signal during a third phase, wherein the first phase is followed by the second phase and the second phase is followed by the third phase, or the second phase is followed by the first phase and the first phase is followed by the third phase.

The present invention also provides a sense margin detecting circuit of memory read operation which includes a first multiplexer, a second multiplexer, a de-multiplexer, and a logic circuit. The first multiplexer includes a first input end coupled to a bit line voltage, a second input end coupled to a reference voltage, and an output end coupled to a first input end of a sense amplifier for selectively outputting the bit line voltage or the reference voltage to the first input end of the sense amplifier based on a first control signal. The second multiplexer includes a first input end coupled to the reference voltage, a second input end coupled to the bit line voltage, and an output end coupled to a second input end of the sense amplifier for selectively outputting the bit line voltage or the reference voltage to the second input end of the sense amplifier based on a second control signal. The de-multiplexer includes a first input end coupled to an output end of the sense amplifier for receiving a data signal outputted by the sense amplifier, a first output end for selectively outputting the data signal based on a third control signal so as to provide a corresponding first data signal during a first phase, and a second output end for selectively outputting the data signal based on the third control signal so as to provide a corresponding second data signal during a second phase. The logic circuit is configured to output a sense margin detecting signal based on the first data signal and the second data signal during a third phase, wherein the first phase is followed by the second phase and the second phase is followed by the third phase, or the second phase is followed by the first phase and the first phase is followed by the third phase.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1A is a schematic block diagram illustrating a memory device according to an embodiment of the present invention.

FIG. 1B is a schematic block diagram illustrating a memory device according to another embodiment of the present invention.

FIG. 2A is a schematic diagram illustrating an implementation of a sense margin detecting circuit in a memory device according to an embodiment of the present invention.

FIG. 2B is a schematic diagram illustrating an implementation of a sense margin detecting circuit in a memory device according to another embodiment of the present invention.

FIG. 2C is a schematic diagram illustrating an implementation of a sense margin detecting circuit in a memory device according to another embodiment of the present invention.

FIG. 3 is a schematic diagram illustrating relevant signals during the operation of a sense margin detecting circuit in a memory device according to an embodiment of the present invention.

FIG. 4 is a flowchart illustrating a method of detecting the sense margin of memory read operation according to an embodiment of the present invention.

FIG. 5 is a schematic diagram illustrating a method of detecting the sense margin of memory read operation according to an embodiment of the present invention.

FIG. 6 is a schematic diagram illustrating a method of detecting the sense margin of memory read operation according to another embodiment of the present invention.

### DETAILED DESCRIPTION

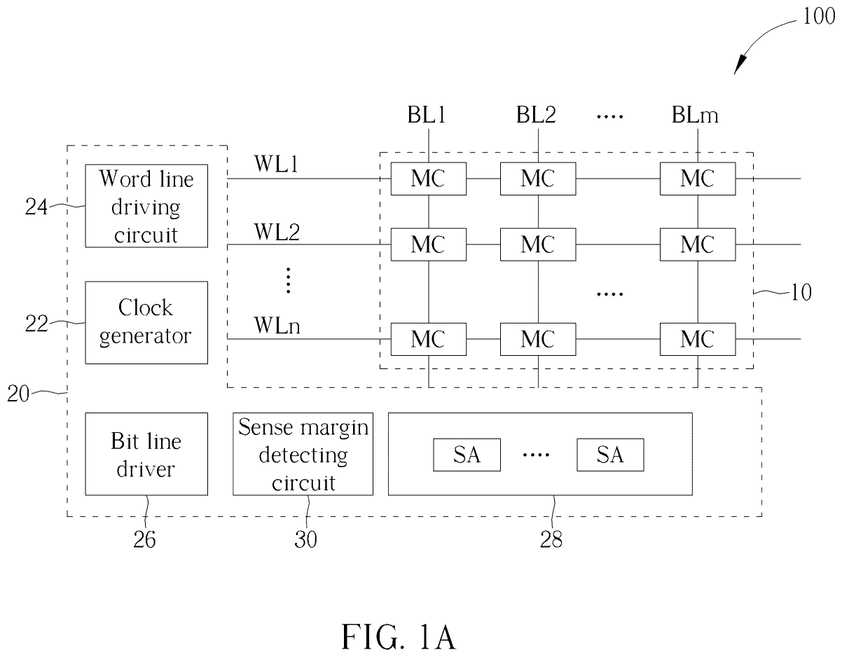

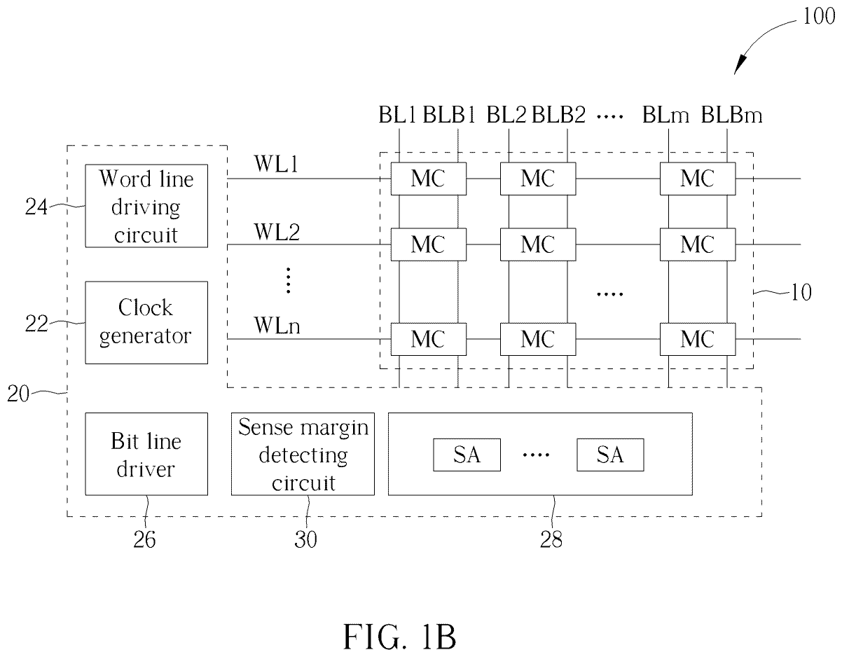

FIGS. 1A and 1B are schematic block diagrams illustrating a memory device 100 according to embodiments of the present invention. The memory device 100 may be an electrical device, an electromechanical device, an electromagnetic device, or any device configured to store bit data represented by a logical state. At least one logical state of the memory device 100 can be programmed during write operation and detected during read operation. In some embodiments, the logic state of the memory device 100 corresponds to the voltage level of the charges stored in the memory device 100. In some embodiments, the logical state of the memory device 100 corresponds to the physical properties of the components in the memory device 100, such as voltage, current, resistance, or magnetic orientation. In some embodiments, the memory device 100 may include one or more single-port (SP), dual-port (DP) or multi-port static random access memory (SRAM) cells or dynamic random access memory (DRAM) cells. In some embodiments, the memory device 100 may include one or more one-time programmable (OTP) memory devices, flash memory devices, random access memory (RAM) devices, resistive RAM devices, ferroelectric RAM (FRAM) devices, magnetoresistive RAM (MRAM) devices, erasable programmable read-only memory (EPROM) devices, electrically erasable programmable read only memory (EEPROM) devices, or similar devices. However, the type of the memory device 100 does not limit the scope of the present invention.

In the present invention, the memory device 100 includes at least one memory array 10 and a control circuit 20. In the embodiment depicted in FIG. 1A, the memory array 10 includes n word lines WL1-WLn, m bit lines BL1-BLm, and a plurality of memory cells MCs, wherein each memory cell MC is coupled to a corresponding word line and a corresponding bit line, and m and n are integers greater than 1. In the embodiment depicted in FIG. 1B, the memory array 10 includes n word lines WL1-WLn, m bit lines BL1-BLm, m complimentary bit lines BLB1-BLBm, and a plurality of memory cells MCs, wherein each memory cell MC is coupled to a corresponding word line, a corresponding bit line and a corresponding complimentary bit line, and m and n are integers greater than 1. The control circuit 200 may include at least a clock generator 22, a word line driving circuit 24, a bit line driver 26, a sense amplifier circuit 28, and a sense margin detecting circuit 30.

In the present invention, the clock generator 22 is configured to provide clock signals required for the operation of each component in the memory device 100, so that the memory device 100 may determine the frequencies of read/write operations based on the clock signals. In some embodiments, the clock generator 22 may include a phase-locked loop (PLL), a delay-locked loop (DLL), a clock multiplier, a clock distributor, or any combination thereof. However, the implementation of the clock generator 22 does not limit the scope of the present invention.

In the present invention, the word line driving circuit 24 may be coupled to the memory array 10 via the word lines WL1-WLn, and is configured to decode the row address of a selected memory cell MC in the memory array 10, so that it may be accessed during the read/write operations. The word line driving circuit 24 may supply a voltage to a selected word line corresponding to the decoded row address, and supply different voltages to other unselected word lines. In some embodiments, the word line driving circuit 24 may include a plurality of word line drivers each coupled to a word line group containing multiple word lines. However, the implementation of the word line driving circuit 24 does not limit the scope of the present invention.

In the present invention, the bit line driving circuit 26 may be coupled to the memory array 10 via the bit lines BL1-BLm, and is configured to decode the column address of a selected memory cell MC of the memory array 10, so that it may be accessed during the read/write operations. The bit line driving circuit 26 may supply a voltage to a selected bit line corresponding to the decoded column address, and supply different voltages to other unselected bit lines. During write operation, the bit line driving circuit 26 is configured to supply a write voltage (also known as a program voltage) to the selected bit line. During read operation, the bit line driving circuit 26 is configured to supply the read voltage to the selected bit line. However, the implementation of the bit line driving circuit 26 does not limit the scope of the present invention.

In the present invention, the sense amplifier circuit 28 may include one or more sense amplifiers SA each coupled to the memory array 10 via its corresponding bit line and its corresponding complementary bit line. Each sense amplifier SA is configured to amplify the weak voltage difference between its corresponding bit line and its corresponding complementary bit line during read operation, so as to accelerate the speed of reading the memory data from the memory cell. In some embodiments, each sense amplifier SA may receive signals from a plurality of corresponding bit lines and complementary bit lines via a multiplexer. In some embodiments, each sense amplifier SA may be a differential amplifier implemented using a plurality of transistors, such as including metal oxide semiconductor field effect transistors (MOSFETs) with a specific type (N-type, P-type, or any combination thereof), bipolar junction transistors (BJTs), high-voltage transistors, high-frequency transistors, fin-effect transistors (FinFETs), planar MOS transistors with elevated source/drains, nanosheet FETs, nanowire FETs, or other components with similar functions. However, the implementation of each sense amplifier SA in the sense amplifier circuit 28 does not limit the scope of the present invention.

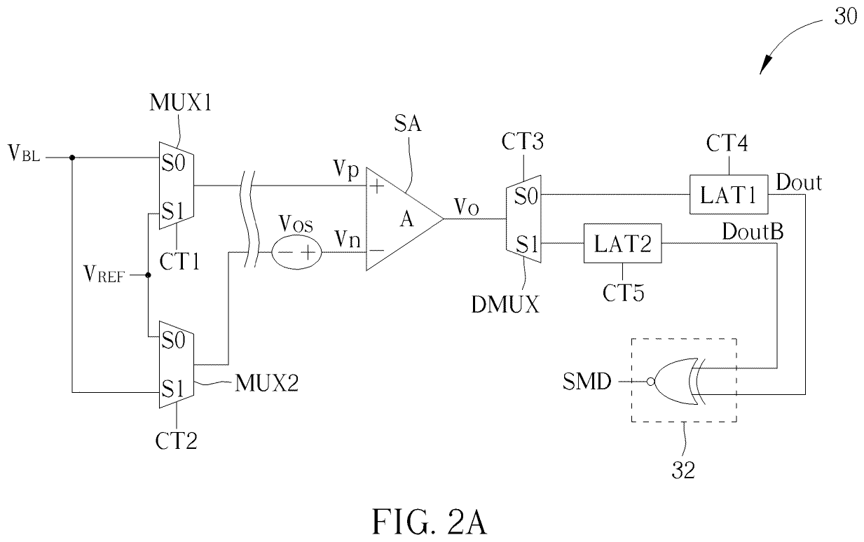

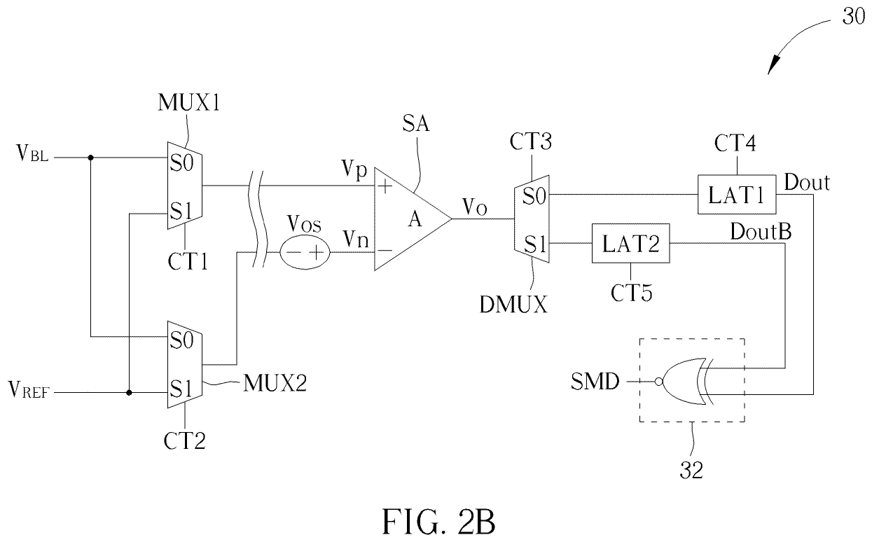

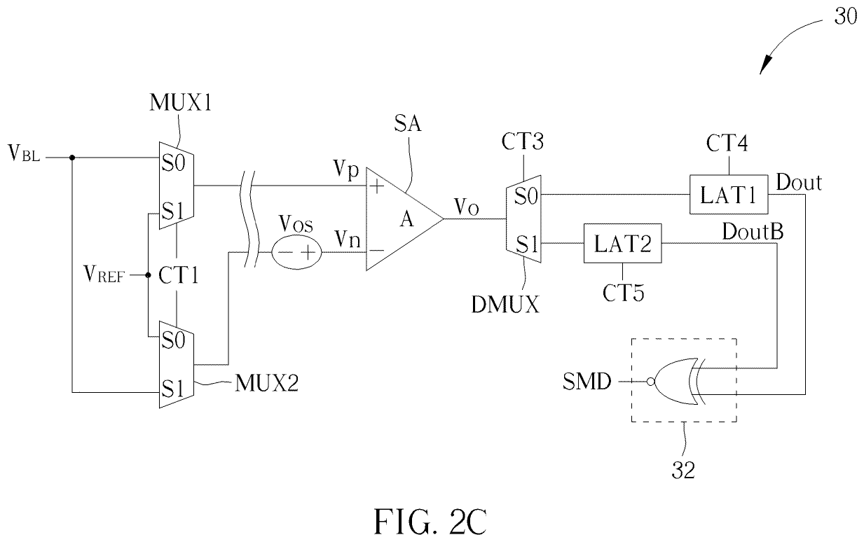

FIGS. 2A-2C are schematic diagrams illustrating the implementation of the sense margin detecting circuit 30 in the memory device 100 according to embodiments of the present invention. The sense margin detecting circuit 30 includes a first multiplexer MUX1, a second multiplexer MUX2, a de-multiplexer DMUX, a logic circuit 32, and latches LAT1 and LAT2. The first multiplexer MUX1 is configured to selectively output the signal of its first input end S0 or its second input end S1 to the first input of the corresponding sense amplifier SA (designated by “+”) based on a corresponding control signal. The second multiplexer MUX2 is configured to selectively output the signal of its first input end S0 or its second input S1 to the second input end of the corresponding sense amplifier SA (designated by “−”) based on a corresponding control signal.

In the embodiment depicted in FIG. 2A, the first input end S0 of the first multiplexer MUX1 is coupled to the bit line voltage V_{BL} of a corresponding bit line, the second input end S1 of the first multiplexer MUX1 is coupled to a reference voltage V_{REF}, and the output end of the first multiplexer MUX1 is coupled to the first input end of a corresponding sense amplifier SA in the sense amplifier circuit 28. The first input end S0 of the second multiplexer MUX2 is coupled to the reference voltage V_{REF}, the second input end S1 of the second multiplexer MUX2 is coupled to the bit line voltage V_{BL}, and the output end of the second multiplexer MUX2 is coupled to the second input end of a corresponding sense amplifier SA in the sense amplifier circuit 28. The first multiplexer MUX1 is configured to selectively output the signal of its first input end S0 or its second input end S1 to the first input end of the corresponding sense amplifier SA based on a control signal CT1, and the second multiplexer MUX2 is configured to selectively output the signal of its first input end S0 or its second input end S1 to the second input end of the corresponding sense amplifier SA based on a control signal CT2. In an embodiment, each of the control signal CT1 and the control signal CT2 may be a signal that periodically switches between a first logic level (e.g., logic 1 level “H”) and a second logic level (e.g., logic 0 level “L”), wherein the control signal CT1 and the control signal CT2 are in-phase signals. More specifically, when the control signals CT1 and CT2 are at the second logic level (e.g., the logic 0 level “L”), the first multiplexer MUX1 is configured to transmit the bit line voltage V_{BL} received by its first input end S0 to the first input end of the corresponding sense amplifier SA, and the second multiplexer MUX2 is configured to transmit the reference voltage V_{REF} received by its first input end S0 to the second input end of the corresponding sense amplifier SA; when the control signals CT1 and CT2 are at the first logic level (e.g., the logic 1 level “H”), the first multiplexer MUX1 is configured to transmit the reference voltage V_{REF} received by its second input end S1 to the first input end of the corresponding sense amplifier SA, and the second multiplexer MUX2 is configured to transmit the bit line voltage V_{BL} received by its second input end S1 to the second input end of the corresponding sense amplifier SA.

In the embodiment depicted in FIG. 2B, the first input end S0 of the first multiplexer MUX1 is coupled to the bit line voltage V_{BL} of a corresponding bit line, the second input end S1 of the first multiplexer MUX1 is coupled to a reference voltage V_{REF}, and the output end of the first multiplexer MUX1 is coupled to the first input end of a corresponding sense amplifier SA in the sense amplifier circuit 28. The first input end S0 of the second multiplexer MUX2 is coupled to the bit line voltage V_{BL}, the second input end S1 of the second multiplexer MUX2 is coupled to the reference voltage V_{REF}, and the output end of the second multiplexer MUX2 is coupled to the second input end of a corresponding sense amplifier SA in the sense amplifier circuit 28. The first multiplexer MUX1 is configured to selectively output the signal of its first input end S0 or its second input end S1 to the first input end of the corresponding sense amplifier SA based on a control signal CT1, and the second multiplexer MUX2 is configured to selectively output the signal of its first input end S0 or its second input end S1 to the second input end of the corresponding sense amplifier SA based on a control signal CT2. In an embodiment, each of the control signal CT1 and the control signal CT2 may be a signal that periodically switches between a first logic level (e.g., logic 1 level “H”) and a second logic level (e.g., logic 0 level “L”), wherein the control signal CT1 and the control signal CT2 are opposite-phase signals. More specifically, when the control signal CT1 is at the second logic level (e.g., the logic 0 level “L”) and the control signal CT2 is at the first logic level (e.g., the logic 1 level “H”), the first multiplexer MUX1 is configured to transmit the bit line voltage V_{BL} received by its first input end S0 to the first input end of the corresponding sense amplifier SA, and the second multiplexer MUX2 is configured to transmit the reference voltage V_{REF} received by its second input end S1 to the second input end of the corresponding sense amplifier SA; when the control signal CT1 is at the first logic level (e.g., the logic 1 level “H”) and the control signal CT2 is at the second logic level (e.g., the logic 0 level “L”, the first multiplexer MUX1 is configured to transmit the reference voltage V_{REF} received by its second input end S1 to the first input end of the corresponding sense amplifier SA, and the second multiplexer MUX2 is configured to transmit the bit line voltage V_{BL} received by its first input end S0 to the second input end of the corresponding sense amplifier SA.

In the embodiment depicted in FIG. 2C, the first input end S0 of the first multiplexer MUX1 is coupled to the bit line voltage V_{BL} of a corresponding bit line, the second input end S1 of the first multiplexer MUX1 is coupled to a reference voltage V_{REF}, and the output end of the first multiplexer MUX1 is coupled to the first input end of a corresponding sense amplifier SA in the sense amplifier circuit 28. The first input end S0 of the second multiplexer MUX2 is coupled to the reference voltage V_{REF}, the second input end S1 of the second multiplexer MUX2 is coupled to the bit line voltage V_{BL}, and the output end of the second multiplexer MUX2 is coupled to the second input end of a corresponding sense amplifier SA in the sense amplifier circuit 28. Each of the first multiplexer MUX1 and the second multiplexer MUX2 is configured to selectively output the signal of its first input end S0 or its second input end S1 to the first input end or the second input end of the corresponding sense amplifier SA based on a control signal CT1. In an embodiment, the control signal CT1 may be a signal that periodically switches between a first logic level (e.g., logic 1 level “H”) and a second logic level (e.g., logic 0 level “L”). More specifically, when the control signal CT1 is at the second logic level (e.g., the logic 0 level “L”), the first multiplexer MUX1 is configured to transmit the bit line voltage V_{BL} received by its first input end S0 to the first input end of the corresponding sense amplifier SA, and the second multiplexer MUX2 is configured to transmit the reference voltage V_{REF} received by its first input end S0 to the second input end of the corresponding sense amplifier SA; when the control signal CT1 is at the first logic level (e.g., the logic 1 level “H”), the first multiplexer MUX1 is configured to transmit the reference voltage V_{REF} received by its second input end S1 to the first input end of the corresponding sense amplifier SA, and the second multiplexer MUX2 is configured to transmit the bit line voltage V_{BL} received by its second input end S1 to the second input end of the corresponding sense amplifier SA.

In the embodiment depicted in FIGS. 2A-2C, Vp represents the voltage established at the first input end of the sense amplifier SA, Vn represents the voltage established at the second input end of the sense amplifier SA, Vo represents the data signal outputted by the sense amplifier SA, and A represents the gain of the sense amplifier SA, wherein Vo=A*(Vp−Vn). Input offset voltage is defined as the DC voltage that must be applied between the two input ends of the sense amplifier SA to force the DC output voltage to zero. In the ideal case, Vp=V_{BL} and Vn=V_{REF}. However, in the real world, process variations and device design constraints may cause non-zero values of the input offset voltage which has an impact on the accuracy of the sense amplifier SA. In the embodiments depicted in FIGS. 2A-2C, Vos is used to designate the influence of all offset voltages present in the memory device 100. Due to variations in the manufacturing processes, metal wirings, ambient temperatures, power supplies and noises, the values of Vos present in different sense amplifiers, different memory cells, different chips and different environments are not constant, and may have positive or negative values. Since the value of Vos may be positive or negative depending on the environment, it is difficult to perform real-time Vos calibration during the application.

The input end of the de-multiplexer DMUX is coupled to the output end of the corresponding sense amplifier SA for receiving the data signal Vo outputted by the sense amplifier SA. The latch LAT1 is coupled between the first output end S0 of the de-multiplexer DMUX and the logic circuit 32, while the latch LAT2 is coupled between the second output end S1 of the de-multiplexer DMUX and the logic circuit 32. The de-multiplexer DMUX is configured to selectively output the data signal Vo via its first output end S0 or its second output end S1 based on a control signal CT3. That is, the outputs of the sense amplifier SA during different phases are outputted to the latch LAT1 and the latch LAT2, respectively. The latches LAT1 and LAT2 are configured to latch the data signal Vo outputted by the sense amplifier SA during different phases based on the control signals CT4 and CT5, respectively, thereby providing the first data signal Dout and the second data signal DoutB, respectively. In an embodiment, each of the control signals CT3-CT5 may be a signal that periodically switches between a first logic level (e.g., logic 1 level “H”) and a second logic level (e.g., logic 0 level “L”), wherein the control signals CT1, CT3 and CT5 are in-phase signals, and the control signals CT4 and CT5 are opposite-phase signals. More specifically, when the control signals CT3 and CT5 are at the second logic level (e.g., logic 0 level “L”) and the control signal CT4 is at the first logic level (e.g., logic 1 level “H”), the de-multiplexer DMUX is configured to transmit the received data signal Vo to the latch LAT1 via its first output end S0, wherein the latch LAT1 in the synchronous state may transmit the data signal Vo as the first data signal Dout, while the latch LAT2 maintains the existing second data signal DoutB; when the control signals CT3 and CT5 are at the first logic level (e.g., logic 1 level “H”) and the control signal CT4 is at the second logic level (e.g., logic 0 level “L”), the de-multiplexer DMUX is configured to transmit the received data signal Vo to the latch LAT2 via its second output end S1, wherein the latch LAT2 in the synchronous state may transmit the data signal Vo as the second data signal DoutB, while the latch LAT1 maintains the existing first data signal Dout.

The first input end of the logic circuit 32 is coupled to the latch LAT1 for receiving the first data signal Dout, and the second input end of the logic circuit 32 is coupled to the latch LAT2 for receiving the second data signal DoutB. The logic circuit 32 is configured to output a sense margin detecting signal SMD based on the first data signal Dout and the second data signal DoutB. In an embodiment, the logic circuit 32 may be an XNOR gate. Under such circumstance, when the first data signal Dout and the second data signal DoutB are both at the first logic level (e.g., logic 1 level “H”) or both at the second logic level (e.g., logic 0 potential “L”), the logic circuit 32 is configured to output the sense margin detecting signal SMD having the first logic level (e.g., logic 1 level “H”); when one of the first data signal Dout and the second data signal DoutB is at the first logic level (such as logic 1 level “H”) and the other one of the first data signal Dout and the second data signal DoutB is at the second logic level (such as logic 0 potential “L”), the logic circuit 32 is configured to output the sense margin detecting signal SMD having the second logic level (such as logic 0 level “L”). However, the implementation of the logic circuit 32 does not limit the scope of the present invention.

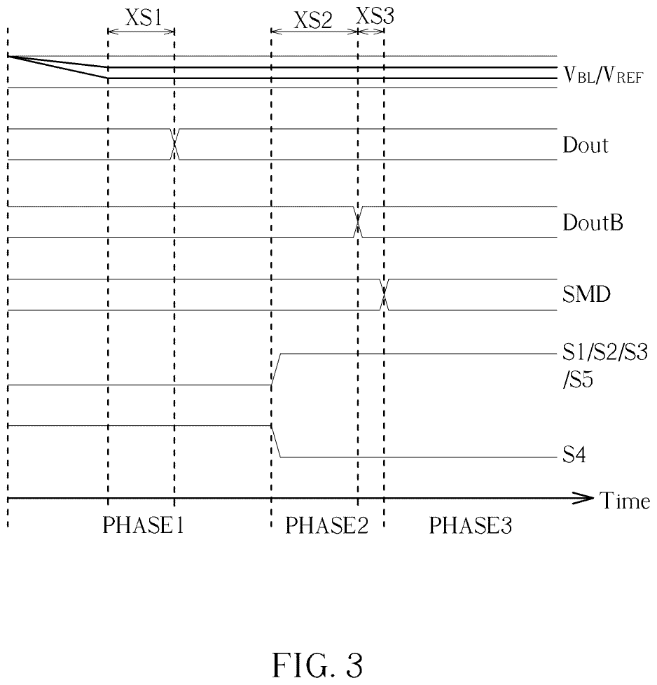

FIG. 3 is a schematic diagram illustrating relevant signals during the operation of the sense margin detecting circuit 30 in the memory device 100 according to an embodiment of the present invention. PHASE1-PHASE3 represents different phases during the operation of the sense margin detecting circuit 30, XS1 represents the sensing delay time of the sense margin detecting circuit 30 during the first phase PHASE1, XS2 represents the sensing delay time of the sense margin detecting circuit 30 during the second phase PHASE2, and XS3 represents the delay time of the logic circuit 32 during the third phase PHASE3.

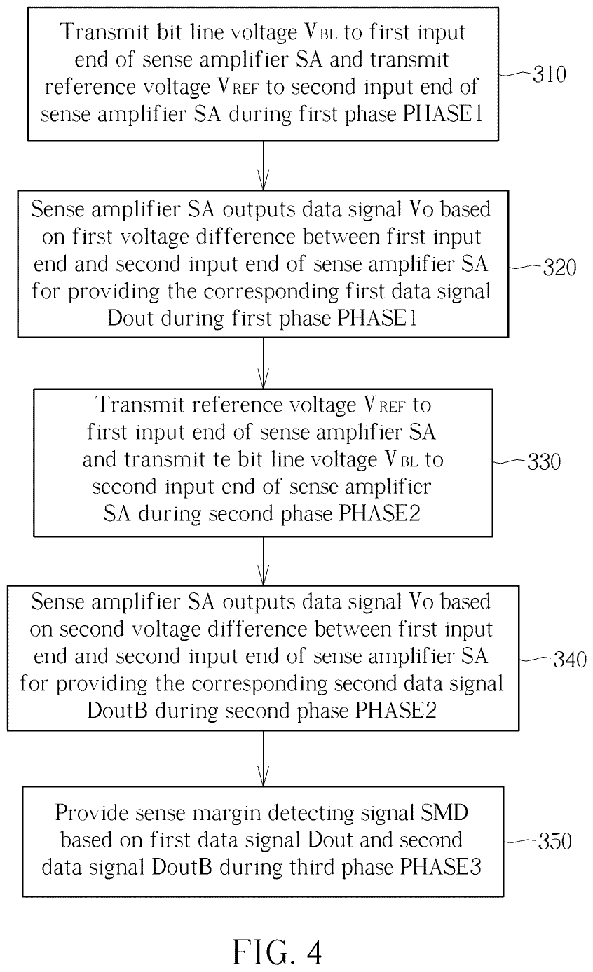

FIG. 4 is a flowchart illustrating a method of detecting the sense margin of memory read operation according to an embodiment of the present invention. The method depicted in FIG. 4 may be executed by the sense margin detecting circuit 30 in the memory device 100, and includes the following steps:

Step 310: transmit the bit line voltage V_{BL} to the first input end of the sense amplifier SA and transmit the reference voltage V_{REF} to the second input end of the sense amplifier SA during the first phase PHASE1.

Step 320: the sense amplifier SA outputs the data signal Vo based on a first voltage difference between the first input end and the second input end of the sense amplifier SA for providing the corresponding first data signal Dout during the first phase PHASE1.

Step 330: transmit the reference voltage V_{REF} to the first input end of the sense amplifier SA and transmit the bit line voltage V_{BL} to the second input end of the sense amplifier SA during the second phase PHASE2.

Step 340: the sense amplifier SA outputs the data signal Vo based on a second voltage difference between the first input end and the second input end of the sense amplifier SA for providing the corresponding second data signal DoutB during the second phase PHASE2.

Step 350: provide the sense margin detecting signal SMD based on the first data signal Dout and the second data signal DoutB during the third phase PHASE3.

In step 310, the bit line voltage V_{BL} is transmitted to the first input end of the sense amplifier SA, and the reference voltage V_{REF} is transmitted to the second input end of the sense amplifier SA during the first stage PHASE1. More specifically, the control signals CT1 and CT3 are both at the second logic level (e.g., logic 0 level “L”) during the first stage PHASE1, and the multiplexer MUX1 is configured to select the bit line voltage V_{BL} received by its first input end S0 to output to the first input end of the sense amplifier SA, and the multiplexer MUX2 is configured to select the reference voltage V_{REF} received by its first input end S0 to output to the second input end of the sense amplifier SA. As previously stated, considering the influence of the offset voltage Vos, the voltage Vp at the first input end of the sense amplifier SA is equal to V_{BL} during the first phase PHASE1, and the voltage Vn at the second input end of the sense amplifier SA is equal to (V_{REF}+Vos) during the first stage PHASE1.

In step 320, the sense amplifier SA is configured to output the data signal Vo based on the first voltage difference (Vp−Vn) between its first input end and its second input end for providing the corresponding first data signal Dout. More specifically, when Vp>Vn, it indicates that V_{BL}>(V_{REF}+Vos). Under such circumstance, the sense amplifier SA is configured to output the positive data signal Vo to the de-multiplexer DMUX, and the de-multiplexer DMUX is configured to transmit the positive data signal Vo to the latch LAT1 via its first output end S0 so as to be latched into the first data signal Dout. On the other hand, when Vp<Vn, it indicates that V_{BL}<(V_{REF}+Vos). Under such circumstance, the sense amplifier SA is configured to output the negative data signal Vo to the de-multiplexer DMUX, and the de-multiplexer DMUX is configured to transmit the negative data signal Vo to the latch LAT1 via its first output end S0 so as to be latched into the first data signal Dout. In other words, Dout=“H” when Vp>Vn during the first phase PHASE1; Dout=“L” when Vp<Vn during the first phase PHASE1.

In step 330, the reference voltage V_{REF} is transmitted to the first input end of the sense amplifier SA, and the bit line voltage V_{BL} is transmitted to the second input end of the sense amplifier SA during the second stage PHASE2. More specifically, the control signals CT1 and CT3 are both at the first logic level (e.g., logic 1 level “H”) during the second stage PHASE2, and the multiplexer MUX1 is configured to select the reference voltage V_{REF} received by its second input end S1 to output to the first input end of the sense amplifier SA, and the multiplexer MUX2 is configured to select the bit line voltage V_{BL} received by its second input end S1 to output to the second input end of the sense amplifier SA. As previously stated, considering the influence of the offset voltage Vos, the voltage Vp at the first input end of the sense amplifier SA is equal to V_{REF} during the second phase PHASE2, and the voltage Vn at the second input end of the sense amplifier SA is equal to (V_{BL}+Vos) during the second phase PHASE2.

In step 340, the sense amplifier SA is configured to output the data signal Vo based on the second voltage difference (Vp−Vn) between its first input end and its second input end for providing the corresponding second data signal DoutB. More specifically, when Vp>Vn, it indicates that V_{BL}<(V_{REF}−Vos). Under such circumstance, the sense amplifier SA is configured to output the positive data signal Vo to the de-multiplexer DMUX, and the de-multiplexer DMUX is configured to transmit the positive data signal Vo to the latch LAT2 via its second output end S1 so as to be latched into the second data signal DoutB. On the other hand, when Vp<Vn, it indicates that V_{BL}>(V_{REF}−Vos). Under such circumstance, the sense amplifier SA is configured to output the negative data signal Vo to the de-multiplexer DMUX, and the de-multiplexer DMUX is configured to transmit the negative data signal Vo to the latch LAT1 via its second output end S1 so as to be latched into the second data signal DoutB. In other words, DoutB=“H” when Vp>Vn during the second phase PHASE2; DoutB=“L” when Vp<Vn during the second phase PHASE2.

In step 350, the logic circuit 32 is configured to provide the sense margin detecting signal SMD based on the first data signal Dout and the second data signal DoutB during the third phase PHASE3. More specifically, during the third stage of PHASE3 when the first data signal Dout and the second data signal DoutB are both at the first logic level (Dout=DoutB=“H”) or both at the second logic level (Dout=DoutB=“L”), the logic circuit 32 is configured to provide the sense margin detecting signal SMD having the first logic level (SMD=“H”) for alerting that the first data signal Dout may exceed the sense margin of the sense amplifier SA. On the other hand, during the third stage of PHASE3 when only one of the first data signal Dout and the second data signal DoutB is the first logic level (Dout=“H” or DoutB=“H”), the logic circuit 32 is configured to provide the sense margin detecting signal SMD having the second logic level (SMD=“L”) for notifying that the first data signal Dout does not exceed the sense margin of the sense amplifier SA.

In the embodiment depicted in FIG. 4, steps 310-350 are sequentially executed in the present method of detecting the sense margin of memory read operation. In another embodiment, steps 330, 340, 310, 320 and 350 may be sequentially executed in the present method of detecting the sense margin of memory read operation.

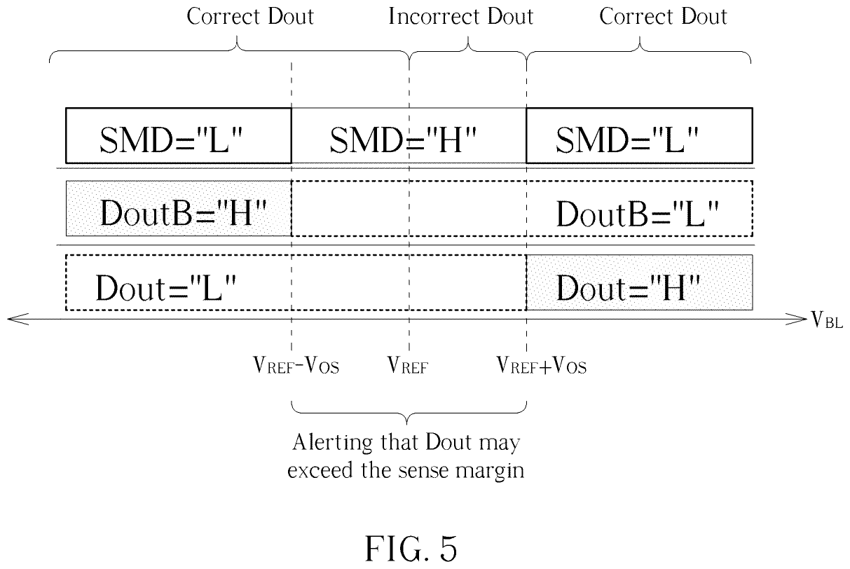

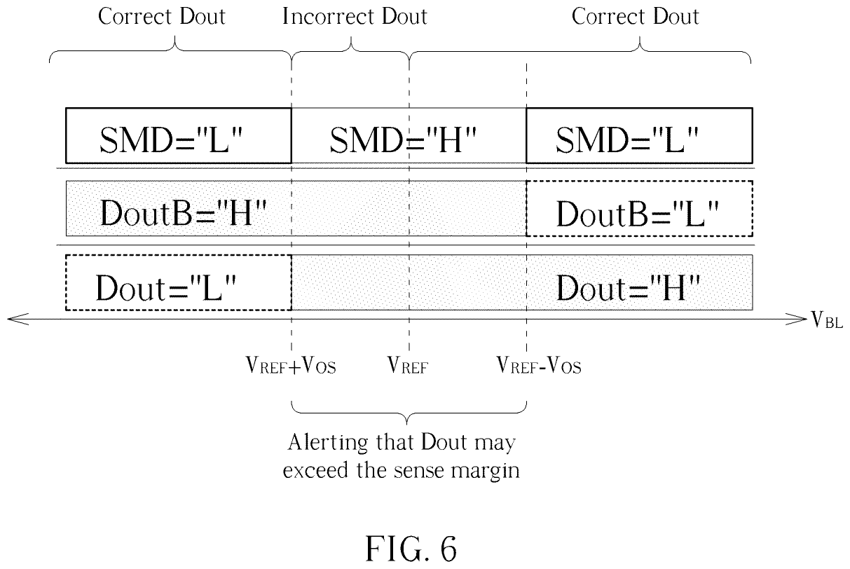

FIGS. 5 and 6 are schematic diagrams illustrating the method of detecting the sense margin of memory read operation according to an embodiment of the present invention. As previously stated, the value of Vos may vary due to variations in the manufacturing processes, metal wirings, ambient temperatures, power supplies and noises. FIG. 5 depicts the embodiment when Vos is positive, while FIG. 6 depicts the embodiment when Vos is negative. As depicted in FIGS. 5 and 6, the prevent invention can alert that the first data signal Dout may exceed the sense margin of the sense amplifier SA according to different values of Vos. However, the alerting range is merely indicative of low data reliability, and the first data signal Dout within the alerting range is not necessarily incorrect.

In an embodiment, the first phase PHASE1 is followed by the second phase PHASE2 and the second phase PHASE2 is followed by the third phase PHASE23, as depicted in FIG. 3. In another embodiment, the second phase PHASE2 is followed by the first phase PHASE1 and the first phase PHASE1 is followed by the third phase PHASE3.

In conclusion, the present invention provides a sense margin detecting method of memory reading operation and a related sense margin detecting circuit capable of alerting that the data signal may exceed the sense margin according to different values of Vos, thereby allowing corresponding actions to be taken against low data reliability.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of detecting a sense margin of memory read operation, comprising:
transmitting a bit line voltage to a first input end of a sense amplifier and transmitting a reference voltage to a second input end of the sense amplifier during a first phase;
the sense amplifier outputting a data signal based on a first voltage difference between the first input end and the second input end of the sense amplifier for providing a corresponding first data signal during the first phase;
transmitting the reference voltage to the first input end of the sense amplifier and transmitting the bit line voltage to the second input end of the sense amplifier during a second phase;
the sense amplifier outputting the data signal based on a second voltage difference between the first input end and the second input end of the sense amplifier for providing a corresponding second data signal during the second phase; and
providing a sense margin detecting signal based on the first data signal and the second data signal during a third phase,
wherein:
the first phase is followed by the second phase and the second phase is followed by the third phase; or
the second phase is followed by the first phase and the first phase is followed by the third phase.

2. The method of claim 1, further comprising:
the sense amplifier outputting the data signal having a second positive value when the first voltage difference is equal to a first positive value during the first phase;
the sense amplifier outputting the data signal having a second negative value when the first voltage difference is equal to a first negative value during the first phase;
the sense amplifier outputting the data signal having a fourth positive value when the second voltage difference is equal to a third positive value during the second phase; and
the sense amplifier outputting the data signal having a fourth negative value when the second voltage difference is equal to a third negative value during the second phase.

3. The method of claim 2, further comprising:
providing the first data signal having a first logic level by latching the data signal having the second positive value when the first voltage difference is equal to the first positive value during the first phase;
providing the first data signal having a second logic level by latching the data signal having the second negative value when the first voltage difference is equal to the first negative value during the first phase;
providing the second data signal having the first logic level by latching the data signal having the fourth positive value when the second voltage difference is equal to the third positive value during the second phase; and
providing the second data signal having the second logic level by latching the data signal having the fourth negative value when the second voltage difference is equal to the third negative value during the second phase, wherein the first logic level is different from the second logic level.

4. The method of claim 3, further comprising:
providing the sense margin detecting signal having a third logic level for alerting that the first data signal may exceed the sense margin when the first data signal and the second data signal are both at the first logic level during the third phase.

5. The method of claim 4, further comprising:
providing the sense margin detecting signal having a fourth logic level for notifying that the first data signal does not exceed the sense margin when one of the first data signal and the second data signal is at the first logic level and an other one of the first data signal and the second data signal is at the second logic level during the third phase, wherein the third logic level is different from the fourth logic level.

6. The method of claim 1, further comprising:
providing the first data signal by latching the data signal outputted by the sense amplifier during the first phase;
providing the second data signal by latching the data signal outputted by the sense amplifier during the second phase;
transmitting the first data signal to a first input end of a logic circuit and transmitting the second data signal to a second input end of the logic circuit during the third phase; and
the logic circuit outputting the sense margin detecting signal based on the first data signal and the second data signal during the third phase.

7. A sense margin detecting circuit of memory read operation, comprising:
a first multiplexer, including:
a first input end coupled to a bit line voltage;
a second input end coupled to a reference voltage; and
an output end coupled to a first input end of a sense amplifier for selectively outputting the bit line voltage or the reference voltage to the first input end of the sense amplifier based on a first control signal;
a second multiplexer, including:
a first input end coupled to the reference voltage;
a second input end coupled to the bit line voltage; and
an output end coupled to a second input end of the sense amplifier for selectively outputting the bit line voltage or the reference voltage to the second input end of the sense amplifier based on a second control signal;
a de-multiplexer, including:
a first input end coupled to an output end of the sense amplifier for receiving a data signal outputted by the sense amplifier;
a first output end for selectively outputting the data signal based on a third control signal so as to provide a corresponding first data signal during a first phase; and
a second output end for selectively outputting the data signal based on the third control signal so as to provide a corresponding second data signal during a second phase; and
a logic circuit configured to output a sense margin detecting signal based on the first data signal and the second data signal during a third phase, wherein:
the first phase is followed by the second phase and the second phase is followed by the third phase; or
the second phase is followed by the first phase and the first phase is followed by the third phase.

8. The sense margin detecting circuit of claim 7, wherein the logic circuit is an XNOR gate.

9. The sense margin detecting circuit of claim 7, wherein:
the sense amplifier is configured to output the data signal having a second positive value when the first voltage difference is equal to a first positive value during the first phase;
the sense amplifier is configured to output the data signal having a second negative value when the first voltage difference is equal to a first negative value during the first phase;
the sense amplifier is configured to output the data signal having a fourth positive value when the second voltage difference is equal to a third positive value during the second phase; and
the sense amplifier is configured to output the data signal having a fourth negative value when the second voltage difference is equal to a third negative value during the second phase.

10. The sense margin detecting circuit of claim 9, further comprising:
a first latch coupled to the first output end of the de-multiplexer and configured to:
provide the first data signal having a first logic level by latching the data signal having the second positive value when the first voltage difference is equal to the first positive value during the first phase; and
provide the first data signal having a second logic level by latching the data signal having the second negative value when the first voltage difference is the first negative value during the first phase; and
a second latch coupled to the second output end of the de-multiplexer and configured to:
provide the second data signal having the first logic level by latching the data signal having the fourth positive value when the second voltage difference is equal to the third positive value during the second phase; and
provide the second data signal having the second logic level by latching the data signal having the fourth negative value when the second voltage difference is equal to the third negative value during the second phase, wherein the first logic level is different from the second logic level.

11. The sense margin detecting circuit of claim 7, wherein the logic circuit is further configured to:
provide the sense margin detecting signal having a third logic level for alerting that the first data signal may exceed the sense margin when the first data signal and the second data signal are both at the first logic level during the third phase.

12. The sense margin detecting circuit of claim 11, wherein the logic circuit is further configured to:
provide the sense margin detecting signal having a fourth logic level for notifying that the first data signal does not exceed the sense margin when one of the first data signal and the second data signal is at the first logic level and an other one of the first data signal and the second data signal is at the second logic level during the third phase, wherein the third logic level is different from the fourth logic level.
